(19) United States
(12) Patent Application Publication
(10) Pub. No.: US 2022/0351971 A1
(43) Pub. Date: Nov. 3, 2022

(54) METHOD FOR PRODUCTION OF MICROWIRES OR NANOWIRES

(71) Applicant: Aledia, Echirolles (FR)

(72) Inventors: Florian Dupont, Grenoble (FR); Jérôme Napierala, Saint Egrève (FR)

(73) Assignee: Aledia, Echirolles (FR)

(21) Appl. No.: 17/621,682

(22) PCT Filed: Jun. 26, 2020
(86) PCT No.: PCT/EP2020/068139

§ 371 Date: Dec. 21, 2021

(30) Foreign Application Priority Data
Jun. 28, 2019 (FR) 1907109

(51) Int. Cl. H01L 21/02; H01L 29/06

(52) U.S. Cl. CPC H01L 21/02603; H01L 21/0262; H01L 21/0254; H01L 29/0669

(57) ABSTRACT

A method of manufacturing a device including micrometer- or nanometer-range wires including a III-V compound, including, for each wire, the forming of at least a portion of the wire by a step of metal-organic vapor epitaxy including the injection into a reactor of a first precursor gas of the group-V element, of a second precursor gas of the group-III element, and of a third precursor gas of an additional element, dopant of the III-V compound, of a gas capable of obtaining a dopant concentration greater than 5.10¹⁹ atoms/cm³, for example, greater than 1.10²⁰ atoms/cm³, in the wire portion in the case where the portion has a homogeneous dopant concentration.

The present patent application claims the priority benefit of French patent application FR19/07109, which is herein incorporated by reference.

### TECHNICAL BACKGROUND

The present disclosure generally concerns devices made up of semiconductor materials and methods of manufacturing the same. The present invention more specifically concerns devices comprising nanometer- or micrometer-range three-dimensional semiconductor elements, especially microwires or nanowires.

### PRIOR ART

Examples of microwires or nanowires comprising a semiconductor material are microwires or nanowires made up of a component mainly containing a group-III element and a group-V element (for example, gallium nitride GaN), called III-V compound hereafter. Such microwires or nanowires enable to manufacture semiconductor devices such as optoelectronic devices. The term optoelectronic devices is used to designate devices capable of converting an electric signal into an electromagnetic radiation or the other way around, and especially devices dedicated to the detection, the measurement, or the emission of an electromagnetic radiation or devices dedicated to photovoltaic applications.

Methods for manufacturing semiconductor material microwires/nanowires should enable to manufacture microwires/nanowires with an accurate and uniform control of the geometry, of the position, and of the crystallographic properties of each microwire/nanowire.

U.S. Pat. No. 9,245,948 describes a method of manufacturing microwires/nanowires made of a III-V compound by metal-organic chemical vapor deposition (MOCVD). Although this method enables to manufacture microwires/nanowires with a satisfactory control of the geometry, of the position, and of the crystallographic properties of each microwire/nanowire, it only enables to manufacture microwires/nanowires having the polarity of the group-V element with a density of the microwires/nanowires corresponding to the ratio of the surface area occupied by the microwires/nanowires on a support to the total surface area of the support, smaller than 20%, particularly smaller than 10%.

### SUMMARY

Thus, an object of an embodiment is to at least partly overcome the disadvantages of the previously-described methods of manufacturing microwires/nanowires made of a III-V compound.

Another object of an embodiment is for the density of the microwires/nanowires to able to be smaller than 10%.

Another object of an embodiment is for each microwire/nanowire to be able to be formed with a polarity of the group-V element or a polarity of the group-III element.

Another object of an embodiment is for each microwire/nanowire to substantially have a single-crystal structure.

Another embodiment provides the possibility of accurately and uniformly controlling the position, the geometry, and the crystallographic properties of each microwire/nanowire.

Another object of an embodiment is for the microwires/nanowires to be able to be manufactured at an industrial scale and at a low cost.

An embodiment provides a method of manufacturing a device comprising micrometer- or nanometer-range wires comprising a III-V compound, comprising, for each wire, the forming of at least a portion of the wire by a step of metal-organic vapor epitaxy comprising the injection into a reactor of a first gas precursor of the group-V element, of a second gas precursor of the group-III element, and of a third gas precursor of an additional element, dopant of the III-V compound, of a gas capable of obtaining a dopant concentration greater than 5.10¹⁹ atoms/cm³, for example, greater than 1.10²⁰ atoms/cm³, in the wire portion in the case where the portion has a homogeneous dopant concentration.

According to an embodiment, the dopant concentration at the surface of the wire portion is greater than 1.10²⁰ atoms/cm³ and/or the wire portion is covered with a layer of a material different from the III-V compound and containing the additional element.

According to an embodiment, the ratio of the flow of the first precursor gas to the flow of the third precursor gas is smaller than or equal to 1,000, for example, equal to 130.

According to an embodiment, the temperature in the reactor at the step of forming of said portion is higher than or equal to 950° C.

According to an embodiment, the temperature in the reactor at the step of forming of said portion is higher than or equal to 1,000° C.

According to an embodiment, the V/III ratio at the step of forming said portion is smaller than or equal to 100.

According to an embodiment, the V/III ratio at the step of forming said portion is smaller than or equal to 50, for example, equal to 5.

According to an embodiment, the method comprises injecting into a reactor a neutral gas and the ratio of the flow of the neutral gas to the flow of the second precursor gas at the step of forming said portion is smaller than 100, for example, equal to 10.

According to an embodiment, the ratio of the flow of the third precursor gas to the flow of the second precursor gas is smaller than 1,000, for example, equal to 130.

According to an embodiment, the ratio of the flow of the third precursor gas to the flow of neutral gas is smaller than 1,000,000 for example, equal to 1,300.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of the structure obtained at a step of an embodiment of a method of manufacturing a device comprising nanowires or microwires;

FIG. 2 is a cross-section view of the structure obtained at another step of the method;

FIG. 3 is a cross-section view of the structure obtained at another step of the method;

FIG. 4 is an image obtained by scanning electron microscopy of a device comprising nanowires or microwires;

FIG. 5 is another image obtained by scanning electron microscopy (SEM) of a device comprising nanowires or microwires;

FIG. 6 is another SEM image of a device comprising nanowires or microwires;

FIG. 7 is another SEM image of a device comprising nanowires or microwires;

FIG. 8 is another SEM image of a device comprising nanowires or microwires;

FIG. 9 is another SEM image of a device comprising nanowires or microwires;

FIG. 10 is another SEM image of a device comprising nanowires or microwires;

FIG. 11 is another SEM image of a device comprising nanowires or microwires;

FIG. 12 is another SEM image of a device comprising nanowires or microwires;

FIG. 13 is another SEM image of a device comprising nanowires or microwires;

FIG. 14 is a partial simplified cross-section view of an embodiment of an optoelectronic device comprising microwires or nanowires; and

FIG. 15 is a partial simplified cross-section view of another embodiment of an optoelectronic device comprising microwires or nanowires.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to a . . . in a normal position of use. Unless specified otherwise, the expressions “around”, “approximately”, “substantially” and “in the order of” signify within 10%, and preferably within 5%. When the expressions “about”, “approximately”, “substantially”, and “in the order of” are used in relation with directions, they mean within 10°, preferably within 5°. Further, it is here considered that the terms “insulating” and “conductive” respectively mean “electrically insulating” and “electrically conductive”.

The present invention relates to the manufacturing of nanometer- or micrometer-range three-dimensional elements, particularly microwires or nanowires.

Term “microwire” or “nanowire” designates a three-dimensional structure of elongated shape along a preferred direction, having at least two dimensions, called minor dimensions, in the range from 5 nm to 5 μm, preferably from 50 nm to 2 μm, more preferably from 50 nm to 1.5 μm, the third dimension, called major dimension or height, being greater than or equal to 1 time, preferably greater than or equal to 3 times, and more preferably still greater than or equal to 5 times, the largest minor dimension. In certain embodiments, the height of each microwire or nanowire may be greater than or equal to 500 nm, preferably in the range from 1 μm to 50 μm. In the following description, the term “wire” is used to mean “microwire” or “nanowire”.

The cross-section of the wires may have different shapes, for example, an oval, circular, or polygonal shape, particularly triangular, rectangular, square, or hexagonal. The term “average diameter” used in relation with a cross-section of a wire designates a quantity associated with the surface area of the wire in this cross-section, for example corresponding to the diameter of the disk having the same surface area as the cross-section of the wire.

The wires mainly comprise, preferably by more than 60 wt. %, more preferably by more than 80 wt. %, at least one III-V compound, for example, a III-N compound. Examples of group-III elements comprise gallium (Ga), indium (In), or aluminum (Al). Examples of III-N compounds are GaN, AN, InN, InGaN, AlGaN, or AlInGaN. Other group-V elements may also be used, for example, phosphorus or arsenic. Generally, the elements in the III-V compound may be combined with different molar fractions. The semiconductor material of the wires may comprise a dopant, for example, silicon ensuring an N-type doping of a III-N compound, or magnesium ensuring a P-type doping of a III-N compound.

Saying that a III-V compound has a polarity of the group-III element or a polarity of the group-V element means that the material grows along a preferred crystal direction and that the last atomic plane, for example, the highest plane when the growth occurs from bottom to top, essentially comprises atoms of the group-III element in the case of the polarity of the group-III element or atoms of the group-V element in the case of the polarity of the group-V element.

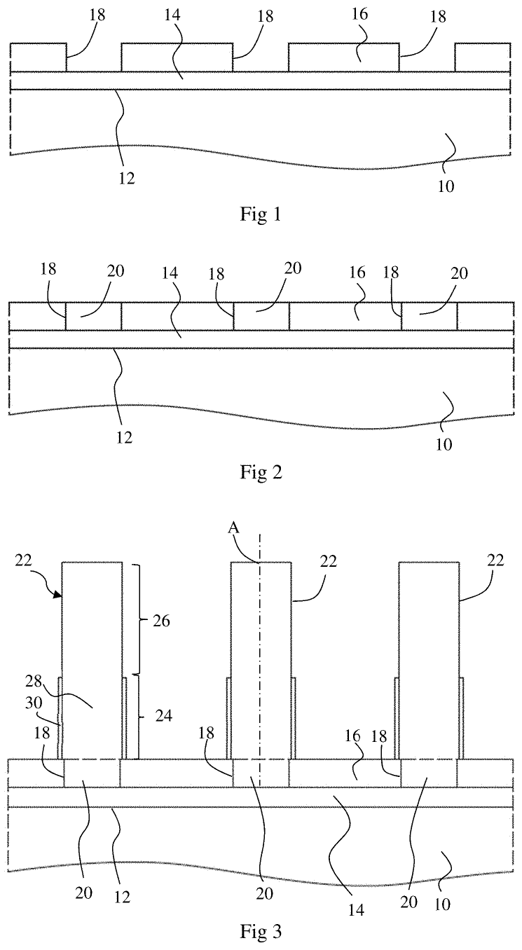

FIGS. 1 to 3 illustrate the structures obtained at successive steps of an embodiment of a method of manufacturing an optoelectronic device comprising wires made of a III-V compound.

FIG. 1 shows the structure obtained after the steps of:
forming on a surface 12 of a substrate 10 a seed layer 14, for example by a method of conformal chemical vapor deposition (CVD) or physical vapor deposition (PVD) type;
forming a growth passivation layer 16 on seed layer 14 for example, by CVD; and
forming openings 18 in growth passivation layer 16, three openings 18 being shown as an example in FIGS. 1 to 3, for example, by an anisotropic etching, particularly reactive ion etching or RIE, inductively coupled plasma etching or ICP etching, or chemical etching.

The cross-section of openings 18 may correspond to the desired cross-section of wires 22 or may be different from the cross-section of the wires that will be obtained. The average diameter of wires 22 may be equal to or greater than the average diameter of openings 18.

Substrate 10 may correspond to a monoblock structure or may correspond to a layer covering a support made of another material. Substrate 10 is preferably a semiconductor substrate, for example, a substrate made of silicon, of germanium, of silicon carbide, of a III-V compound, such as GaN or GaAs, or a ZnO substrate. Preferably, substrate 10 is a single-crystal silicon substrate. Preferably, it is a semiconductor substrate compatible with the manufacturing methods implemented in microelectronics. Substrate 10 may correspond to a multilayer structure of silicon-on-insulator type, also called SOI. As a variant, the substrate may be insulating, for example, made of sapphire or of spinel.

Seed layer 14 is made of a material favoring the growth of wires. As an example, the material forming seed layer 14 may be a nitride, a carbide, or a boride of a transition metal from column IV, V, or VI of the periodic table of elements or a combination of these compounds. As an example, seed layer 14 may be made of aluminum nitride (AlN), of boron (B), of boron nitride (BN), of titanium (Ti), or titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB2), of zirconium nitride (ZrN), of silicon carbide (SiC), of tantalum carbide nitride (TaCN), of magnesium nitride in MgxNy form, where x is approximately equal to 3 and y is approximately equal to 2, for example, magnesium nitride according to form Mg3N2 or magnesium gallium nitride (MgGaN), of tungsten (W), of tungsten nitride (WN), or of a combination thereof. Seed layer 14 may have a monolayer structure or may correspond to a stack of at least two layers, each layer being for example made of one of the previously-described materials.

According to an embodiment, seed layer 14 may be absent. According to another embodiment, seed layer 14 may be replaced with seed pads, for example, formed in openings 18.

The material forming seed layer 14 may be made of a material favoring the growth of wires according to the polarity of the group-III element or the growth of wires according to the polarity of the group-V element.

Growth passivation layer 16 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of aluminum oxide (Al₂O₃), of hafnium oxide (HfO₂), or of diamond. Growth passivation layer 16 may have a monolayer structure or may correspond to a stack of two layers or of more than two layers. When growth passivation layer 16 corresponds to a stack of at least two layers, the upper layer of the stack is of insulating type, for example, made of a dielectric material. The lower layer(s) of the stack between seed layer 14 and the upper insulating layer may be made of a dielectric material. As a variation, the lower layer(s) may be made of a semiconductor or metallic material, for example, of aluminum nitride (AlN), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum nitride and carbide (TaCN), of tungsten (W), or of tungsten nitride (WN).

FIG. 2 shows the structure obtained after the growth in openings 18, in contact with seed layer 14, of seeds 20 made of the same III-V compounds as the wires, for example, by MOCVD.

FIG. 3 shows the structure obtained after the growth of wires 22 from seeds 20, each wire 22 extending from substrate 10 through one of openings 18. Each wire 22 extends along a substantially rectilinear axis A substantially perpendicular to surface 12.

Each wire 22 may comprise a lower portion 24, the closest to substrate 10, extending in an upper portion 26. Lower portion 24 comprise a core 28 comprising the III-V material doped with a dopant of a first conductivity type, for example, of type N, and a layer 30 covering the lateral wall of core 28, comprising the dopant by more than 30 wt. %, possibly with the group-III element or with the group-V element. Upper portion 26 is made of the III-V material, non-intentionally doped. According to an embodiment, upper portion 26 may be absent. The lower portions 24 of wires 22 are formed in a first growth phase and the upper portions 26 of wires 22 are formed in a second growth phase.

The method of growing seeds 20 and wires 22 is a MOCVD method, also known as metal-organic vapor phase epitaxy (MOVPE). The growth conditions of seeds 20 are different from those of wires 22, the growth conditions of seeds 20 favoring the growth of the III-V compound on seed layer 14 without favoring a specific growth direction. According to another embodiment, the step of growth of seeds 20 is not present and wires 22 are directly formed on seed layer 14 in openings 18.

As an example, the method may comprise injecting into a reactor a precursor of a group-III element and a precursor of a group-V element. Examples of precursors of group-III elements are trimethylgallium (TMGa), triethylgallium (TEGa), trimethylindium (TMIn), or trimethylaluminum (TMAl). Examples of precursors of group-V elements are ammonia (NH₃), tertiarybutylphosphine (TBP), arsine (AsH₃), or unsymmetrical dimethylhydrazine (UDMH).

According to an embodiment, the temperature in the reactor during the growth of seeds 20 is lower than or equal to 1,000° C., preferably lower than or equal to 820° C.

According to an embodiment, the ratio of the flow rate of the group-V element precursor gas to the flow rate of the group-III element precursor gas, or V/III ratio, for the forming of seeds 20 is greater than or equal to 1,000, preferably greater than or equal to 5,000.

Preferably, the temperature in the reactor at the step of forming seeds 20 is lower than the temperature in the reactor at the step of forming wires 22. Preferably, the V/III ratio at the step of forming seeds 20 is greater than the V/III ratio at the step of forming wires 22.

According to an embodiment, the temperature in the reactor at the step of forming wires 22 is higher than or equal to 950° C., preferably higher than or equal to 1,000° C., more preferably higher than or equal to 1,050° C., for example, approximately 1,095° C.

According to an embodiment, the V/III ratio at the step of forming wires 22 is smaller than or equal to 100, preferably smaller than or equal to 50, more preferably smaller than or equal to 20, more preferably smaller than or equal to 10, for example, approximately 5.

According to an embodiment, the pressure in the reactor at the step of forming wires 22 is in the range from 666 Pa (5 Torr) to 199,984 (1,500 Torr).

According to an embodiment of the invention, at least in the first phase of growth of the wires 22 of the III-V compound, a precursor of an additional element is added in excess, in addition to the precursors of the III-V compound. The additional element may be silicon (Si). Examples of precursors of silicon are silane (SiH₄), disilane (S₂H₆), and dichlorosilane (SiH₂Cl₂).

According to an embodiment of the invention, the ratio of the flow of the gas precursor of the group-V element to the flow of the gas precursor of the additional element is smaller than or equal to 1,000, preferably smaller than or equal to 500, more preferably smaller than or equal to 200, for example, approximately 140. According to an embodiment, the ratio of the flow of the gas precursor of the additional element to the flow of the gas precursor of the group-III element is greater than 3*10⁻⁴. The flow of the gas precursor is that which would enable to obtain a dopant concentration in core 28 of the lower portion 24 of wire 22 greater than 5.10¹⁹ atoms/cm³, preferably greater than 10²⁰ atoms/cm³, if all the dopant was incorporated in core 28 of the lower portion 24 of wire 22. However, since the phase of growth of lower portion 24 causes the forming of the layer 30 containing a significant proportion of the dopant, the dopant concentration in core 28 really obtained is smaller than 10²⁰ atoms/cm³.

According to an embodiment, during the growth of seeds 20 and of wires 22, a carrier gas which ensures the diffusion of the metal-organic precursors all the way into the reactor may be used. The carrier gas may comprise a neutral gas or a mixture of neutral gas, particularly a mixture of nitrogen (N₂) and of hydrogen (H₂). The carrier gas may be laden with a metal-organic precursor in a bubbler. According to an embodiment, the volume concentration of hydrogen in the carrier gas is in the range from 0% to 100%, for example, approximately 20%.

The ratio of the flow of carrier gas to the flow of precursor gas of the group-III element is smaller than 100, for example, equal to 10. The ratio of the flow of the precursor gas of the additional element to the flow of the carrier gas is smaller than 1,000,000, for example, equal to 1,300.

The presence of silane among the precursor gases causes the incorporation of silicon within the GaN compound. Further, this results in the forming of silicon nitride layer 30 which covers the periphery of lower portion 24, except for the top along the growth of the lower portion 24 of wire 22.

For the growth of upper portion 26, the previously-described operating conditions of the MOCVD reactor are, as an example, maintained, but for the fact that the silane flow in the reactor is decreased, for example, by a factor greater than or equal to 10, or stopped. Even when the silane flow is stopped, an active portion may be N-type doped due to the diffusion in this active portion of dopants originating from the adjacent passivated portions or due to the residual doping of GaN.

Tests have been performed. First, second, or third substrates have been used. The first substrate corresponds to a sapphire support covered with a GaN, favoring the growth of GaN according to the metal polarity. The second substrate corresponds to a silicon support covered with an AN seed layer, favoring the growth of GaN according to the metal polarity. The third substrate corresponds to a substrate favoring the growth of GaN according to the nitrogen polarity. Growth passivation layer 16 comprised a stack of a Si₃N₄ layer having a 80-nm thickness and a SiO₂ layer having a 50-nm thickness. Openings 18 had a circular cross-section. Openings 18 were arranged in rows and in columns. Three MOCVD methods with different parameters have been implemented. Unless otherwise indicated, in the following tests, the values of the parameters of the methods are those indicated in table 1 hereafter.

TABLE 1

| | Method P1 | Method P2 | Method P3 |
|---|---|---|---|
| Temperature (° C.) | 1,095 | 1,017 | 1,095 |
| Duration(s) | 480 | 481 | 150 |
| Pressure (Pa) | 13.33 | 56.67 | 13.33 |
| Carrier gas | N₂, H₂ | N₂, H₂ | N₂, H₂ |
| Ga precursor gas | TMGa | TMGa | TMGa |
| Dopant precursor gas | SiH₄ | SiH₄ | SiH₄ |
| Flow of the Ga precursor gas | 2,336 | 2,225 | 3,518 |
| (μmol/min) | | | |
| V/III ratio | 5 | 11 | 5 |
| H₂/(H₂ + N₂) ratio (%) | 10 | 40 | 20 |
| Ga precursor flux/dopant | 38,378 | 3,253 | 138 |
| precursor flux | | | |

### Comparison Method P1

Method P1 corresponds to a known nanowire forming method called low-flow or LF method. It is a MOCVD method which enables to form GaN wires of a Ga polarity only. During the implementation of method P1, seed layer 14 thus favors the growth of the wires of Ga polarity.

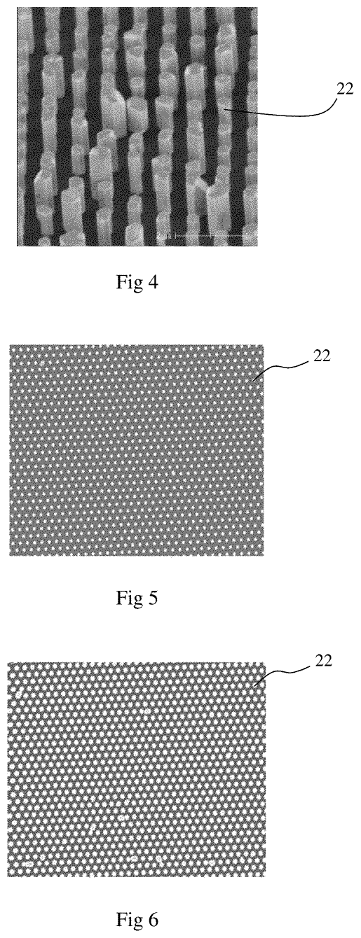

FIG. 4 is an image obtained by scanning electron microscopy of wires 22 manufacturing according to method P1 when the average diameter of each wire 22 was 350 nm and when the interval between two adjacent openings 18 of a same row was 800 nm. The third substrate has been used. As shown in FIG. 4, the obtained dimensions of wires 22, particularly the average diameter and the height, are not uniform.

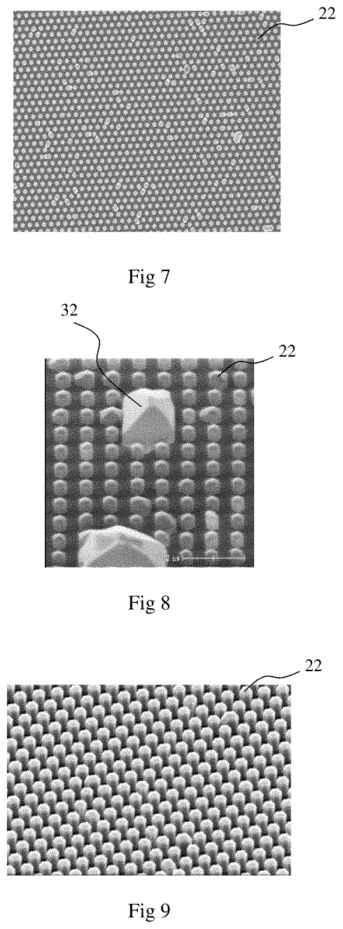

FIGS. 5, 6, and 7 each are a top view obtained by scanning electron microscopy of wires 22 manufacturing according to method P1 when the average diameter of openings 18 was respectively 100 nm, 150 nm, and 200 nm and when the interval between two adjacent openings 18 of a same row respectively was 400 nm, 330 nm, and 800 nm. The first substrate has been used. As shown in the drawings, the number of defects increases when the average diameter of openings 18 increases.

FIG. 8 is an image obtained by scanning electron microscopy of wires 22 manufactured according to method P1 when the average diameter of each wire 22 was 420 nm and when the interval between two adjacent openings 18 of a same row was 800 nm. The second substrate has been used. As shown in FIG. 8, GaN blocks 32 form when the mesh openness increases.

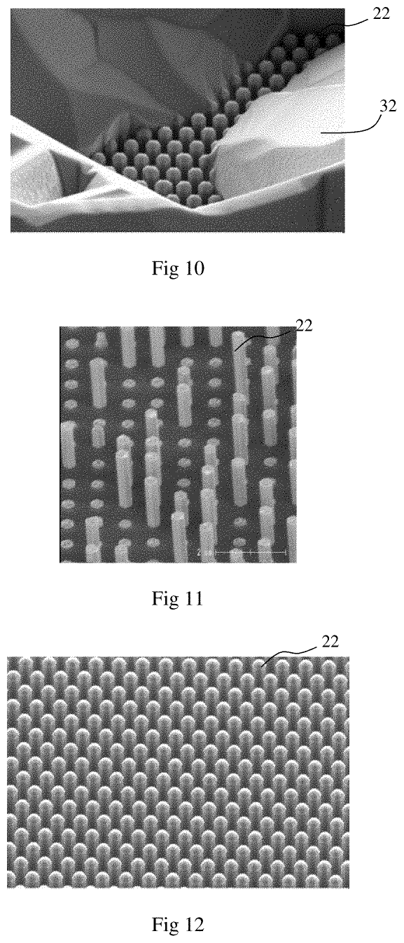

FIGS. 9 and 10 each are a view obtained by scanning electron microscopy of wires 22 manufactured according to method P1 when the average diameter of openings 18 was respectively 100 nm, the interval between two adjacent openings 18 of a same row was 300 nm, and when the processing times were respectively 2 minutes and 30 minutes. The first substrate has been used. As shown in FIGS. 9 and 10, beyond a given time period in the order of 5 minutes, the length of wires 22 increases little and GaN blocks 32 form. Method P1 thus does not enable to obtain wires having a height greater than 800 nm.

### Comparison Method P2

Method P2 corresponds to a known nanowire forming method such as that described in U.S. Pat. No. 9,245,948. Method P2 is a MOCVD method which enables to form GaN wires only having an N polarity. The third substrate has been used. The seed layer thus favors the growth of wires 22 of polarity N polarity. Method P2 provides satisfactory results for low densities of wires 22, particularly smaller than 5%, but is not adapted to higher wire densities. For method P2, the flow of the precursor of the additional element, here SiH4, is selected to obtain a concentration of the Si dopant in the lower portion 24 of wire 22 of 1019 atoms/cm3 if the lower portion 24 had a homogeneous composition.

FIG. 11 is an image obtained by scanning electron microscopy obtained with method P2 when the average diameter of each wire was 350 nm and when the interval between two adjacent openings 18 of a same row was 800 nm, which corresponds to a targeted density of wires of approximately 20%. As shown in FIG. 11, for many openings 18, there is no growth of wires 22. A filling rate smaller than 50% is obtained.

### Method P3

Method P3 corresponds to an embodiment of the method according to the invention.

FIG. 12 is a scanning electron microscopy image obtained with method P3, when the first substrate has been used. The first substrate favors the growth of the wires of Ga polarity. The average diameter of each wire was 220 nm and the interval between two adjacent openings 18 of a same row was 400 nm. There is no visible defect.

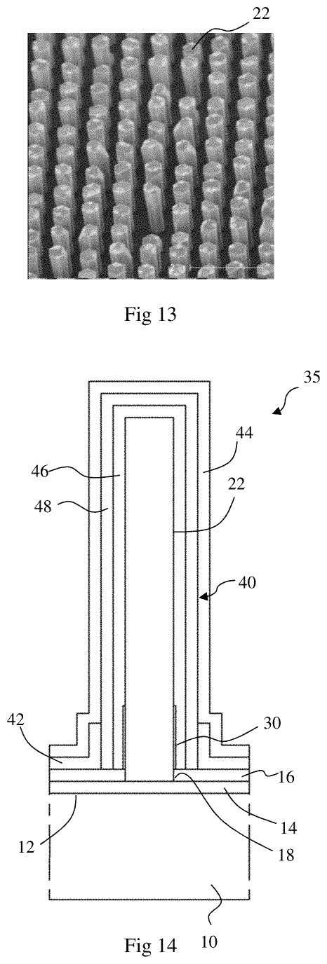

FIG. 13 is a scanning electron microscopy image obtained with method P3, when the third substrate, thus favoring the growth of the wires of N polarity, has been used. The average diameter of each wire was 540 nm and the interval between two adjacent openings 18 of a same row was approximately 800 nm. Few defects are visible and a growth rate, corresponding to the number of wires growing in each opening, greater than 95% is obtained.

An example of application of the previously-described devices comprising wires concerns optoelectronic devices. Examples of optoelectronic devices comprise optoelectronic devices comprising light-emitting diodes, devices dedicated to the detection or to the measurement of an electromagnetic radiation, or devices dedicated to photovoltaic applications.

FIG. 14 is a partial simplified cross-section view of an embodiment of an optoelectronic device 35 comprising light-emitting diodes.

FIG. 14 shows a structure comprising, from bottom to top:
semiconductor substrate 10;
seed layer 14 made of a material favoring the growth of wires and arranged on surface 12;
growth passivation layer 16 covering seed layer 14 and comprising openings 18 exposing portions of seed layer 14;
wires 22, one wire being shown, each wire 22 projecting from one of openings 19;
for each wire 22, a shell 40 comprising a stack of semiconductor layers covering the lateral surfaces and the upper surface of wire 22;
an insulating layer 42 extending on the lateral sides of a lower portion of shell 40 and on growth passivation layer 16 between wires 22; and
a layer 44 forming an electrode covering each shell 40 and further extending on insulating layer 42.

The assembly formed by each wire 22 and the associated shell 40 forms a light-emitting diode. Shell 28 may comprise a stack of a plurality of layers particularly comprising an active layer 46 and a bonding layer 48. The active layer is the layer from which the majority of the radiation supplied by light-emitting diode DEL is emitted. According to an example, active layer 44 may comprise confinement means, such as multiple quantum wells. The bonding layer may comprise a stack of semiconductor layers of the same III-V material as wire 22 but of the opposite conductivity type.

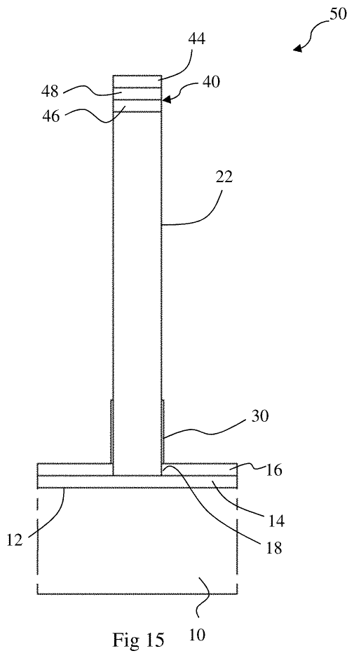

FIG. 15 is a partial simplified cross-section view of an embodiment of an optoelectronic device 50 comprising light-emitting diodes where, as compared with the optoelectronic device 35 shown in FIG. 14, shell 38 and electrode 40 are only present at the top of wire 22.

Various embodiments and variants have been described. Those skilled in the art will understand that certain features of these various embodiments and variants may be combined, and other variants will occur to those skilled in the art. Finally, the practical implementation of the described embodiments and variants is within the abilities of those skilled in the art based on the functional indications given hereabove.

1. A method of manufacturing a device comprising micrometer- or nanometer-range wires comprising a III-V compound, comprising, for each wire, the forming of at least a portion of the wire by a step of metal-organic vapor epitaxy comprising the injection into a reactor of a first gas precursor of the group-V element, of a second gas precursor of the group-III element, and of a third gas precursor of an additional element, dopant of the III-V compound, with a ratio of the flow of the third gas precursor of an additional element to the flow of the second gas precursor of the group-III element greater than 3*10⁻⁴ to obtain a dopant concentration greater than 5.10¹⁹ atoms/cm³, for example, greater than 1.10²⁰ atoms/cm³, in the wire portion in the case where the portion has a homogeneous dopant concentration.

2. The method according to claim 1, wherein the dopant concentration at the surface of the wire portion is greater than 1.10²⁰ atoms/cm³ and/or the wire portion is covered with a layer of a material different from the III-V compound and containing the additional element.

3. The method according to claim 1, wherein the ratio of the flow of the first precursor gas to the flow of the third precursor gas is smaller than or equal to 1,000, for example, equal to 130.

4. The method according to claim 1, wherein the temperature in the reactor at the step of forming said portion is greater than or equal to 950° C.

5. The method according to claim 4, wherein the temperature in the reactor at the step of forming said portion is greater than or equal to 1,000° C.

6. The method according to claim 1 to 5, wherein the V/III ratio at the step of forming said portion is smaller than or equal to 100.

7. The method according to claim 6, wherein the V/III ratio at the step of forming said portion is smaller than or equal to 50, for example, equal to 5.

8. The method according to claim 1, comprising the injection into a reactor of a neutral gas and where the ratio of the neutral gas flow to the flow of the second precursor gas at the step of forming said portion is smaller than 100, for example, equal to 10.

9. The method according to claim 8, wherein the ratio of the flow of the third precursor gas to the flow of the second precursor gas is smaller than 1,000, for example, equal to 130.

10. The method according to claim 8, wherein the ratio of the flow of the third precursor gas to the flow of the neutral gas is smaller than 1,000,000, for example, equal to 1,300.

11. The method according to claim 1, comprising the successive forming of at least a first portion of the wire and a second portion of the wire by steps of vapor phase metal-organic epitaxy comprising the injection into the reactor of the first gas precursor of the group-V element, of the second gas precursor of the group-III element, and of the third gas precursor of an additional element, dopant of the III-V compound, of said gas capable of forming the first portion to obtain a dopant concentration greater than 5.10¹⁹ atoms/cm³, for example, greater than 1.10²⁰ atoms/cm³, in the first portion of the wire in the case where the first portion has a homogeneous dopant concentration, the flow of the third precursor gas being decreased or stopped for the forming of the second portion.
